(19) United States
(12) Patent Application Publication
(10) Pub. No.: US 2024/0194605 A1
(43) Pub. Date: Jun. 13, 2024

(54) POST-TREATMENT FOR REMOVING RESIDUES FROM DIELECTRIC SURFACE

(71) Applicant: Applied Materials, Inc., Santa Clara, CA (US)

(72) Inventors: Mohammad Mahdi TAVAKOLI, Santa Clara, CA (US); Avgerinos V. GELATOS, Scotts Valley, CA (US); Jiajie CEN, Santa Clara, CA (US); Kevin KASHEFI, Dublin, CA (US); Joung Joo LEE, San Jose, CA (US); Zhihui LIU, Santa Clara, CA (US); Yang ZHOU, Santa Clara, CA (US); Zhiyuan WU, San Jose, CA (US); Meng-Shan WU, Santa Clara, CA (US)

(21) Appl. No.: 18/534,333

(22) Filed: Dec. 8, 2023

Related U.S. Application Data
(60) Provisional application No. 63/431,952, filed on Dec. 12, 2022.

(51) Int. Cl. H01L 23/532; H01J 37/32; H01L 21/02; H01L 21/768

(52) U.S. Cl. CPC H01L 23/53266; H01J 37/32357; H01L 21/02068; H01L 21/76843; H01L 21/76877; H01J 2237/335

(57) ABSTRACT

A semiconductor structure includes a first level comprising a metal layer within a first dielectric layer formed on a substrate, a second level formed on the first level, the second level comprising an interconnect within a second dielectric layer and a barrier layer formed around the interconnect, and a metal capping layer disposed at an interface between the metal layer and the interconnect, wherein the metal capping layer comprises tungsten (W) and has a thickness of between 20 Å and 40 Å.

### CROSS-REFERENCE TO RELATED APPLICATIONS

This application claims priority to U.S. Provisional Application Ser. No. 63/431,952 filed Dec. 12, 2022, which is herein incorporated by reference in its entirety.

### BACKGROUND

### Field

Embodiments herein are directed to methods used in electronic device manufacturing, and more particularly, to a process to grow a selective tungsten (W) capping layer on a tungsten (W) via during a back-end-of-the-line (BEOL) process.

### Description of the Related Art

Tungsten (W) is widely used in integrated circuit (IC) device manufacturing to form conductive features where relatively low electrical resistance and relativity high resistance to electromigration are desired. For example, tungsten may be used as a metal fill material to form source contacts, drain contacts, metal gate fill, gate contacts, interconnects (e.g., horizontal features formed in a surface of a dielectric material layer), and vias (e.g., vertical features formed through a dielectric material layer to connect other interconnect features disposed there above and there below). Due to its relativity low resistivity, tungsten is also commonly used to form interconnects at M0 level of IC devices, and also bit lines and word lines used to address individual memory cells in a memory cell array of a three-dimensional NAND (3D NAND) device.

Conventional post-processing treatment methods used to remove tungsten and chlorine residues from dielectric surfaces during a device fabrication process have been found to damage the dielectric surfaces.

Therefore, there is a need for a process that solves these problems.

### SUMMARY

Embodiments of the present disclosure provide a semiconductor structure. The semiconductor structure includes a first level comprising a metal layer within a first dielectric layer formed on a substrate, a second level formed on the first level, the second level comprising an interconnect within a second dielectric layer and a barrier layer formed around the interconnect, and a metal capping layer disposed at an interface between the metal layer and the interconnect, wherein the metal capping layer comprises tungsten (W) and has a thickness of between 20 Å and 40 Å.

Embodiments of the present disclosure provide a method of post-treatment in a middle-end-of-line (MEOL) portion of a semiconductor structure. The method includes performing a first pre-clean process to remove residues from a surface of a metal layer within a via formed in a dielectric layer, performing a first soak process, including a second pre-clean process to remove metal oxides from the surface of the metal layer within the via, and a fluorine-free tungsten (FFW) growth process to form a metal capping layer on the surface of the metal layer, and performing a second soak process to remove residues from exposed surfaces of the dielectric layer on inner sidewalls of the via.

Embodiments of the present disclosure provide a method of forming a middle-end-of-line (MEOL) portion of a semiconductor structure. The method includes performing a first pre-clean process to remove residues from a surface of a metal layer within a via formed in a dielectric layer, performing a first soak process, including a second pre-clean process to remove metal oxides from the surface of the metal layer within the via, and a fluorine-free tungsten (FFW) growth process to form a metal capping layer on the surface of the metal layer, performing a second soak process to remove residues from inner sidewalls of the via, performing a third pre-clean process to remove residues from the surface of the metal layer within the via, performing a first selective deposition process to form a passivation layer selectively on an exposed surface of the metal capping layer, performing a second selective deposition process to form a barrier layer on inner sidewalls of the via, performing a removal process to remove the passivation layer from the surface of the metal layer, and performing a metal fill process to fill the via with conductive via fill material.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 is a schematic top view of a multi-chamber processing system 100, according to one or more embodiments of the present disclosure.

FIGS. 2A and 2B are schematic views of an exemplary semiconductor structure 200. FIG. 2A illustrates a middle-end-of-line (MEOL) portion 200A of the semiconductor structure 200. FIG. 2B illustrates a back-end-of-the-line (BEOL) portion 200B of the semiconductor structure 200.

FIG. 3 depicts a process flow diagram of a method of forming a semiconductor structure having the MEOL portion and the BEOL portion, shown in FIGS. 2A and 2B, according to one or more embodiments of the present disclosure.

FIGS. 4A, 4B, 4C, 4D, 4E, and 4F are cross-sectional views of a portion of the semiconductor structure 200 corresponding to various states of the method of FIG. 3.

To facilitate understanding, identical reference numerals have been used, where possible, to designate identical elements that are common to the figures. It is contemplated that elements and features of one embodiment may be beneficially incorporated in other embodiments without further recitation. In the figures and the following description, an orthogonal coordinate system including an X-axis, a Y-axis, and a Z-axis is used. The directions represented by the arrows in the drawings are assumed to be positive directions for convenience. It is contemplated that elements disclosed in some embodiments may be beneficially utilized on other implementations without specific recitation.

### DETAILED DESCRIPTION

Embodiments herein are generally directed to electronic device manufacturing and, more particularly, to systems and a method used to prepare and grow a selective tungsten (W) capping layer on a tungsten (W) via during a back-end-of-the-line (BEOL) process.

The methods disclosed herein include a post-treatment (H₂O soak) that significantly reduces the level of tungsten/chloride residues and recovers a tantalum nitride (TaN) barrier better than conventional processes. Conventional post-treatment methods, such as a remote plasma assisted process or a capacitively coupled plasma (CCP) process, are not as effective as the H₂O soak disclosed herein for tungsten/chloride removal and cannot fully recover the TaN barrier resistance. More importantly, conventional post-treatments methods damage the dielectric surface, which has been found not to be the case for the H₂O soak disclosed herein. In the methods described herein, the H₂O soak process can be performed in a chamber that is integrated in a multi-chamber processing system.

### Processing System Example

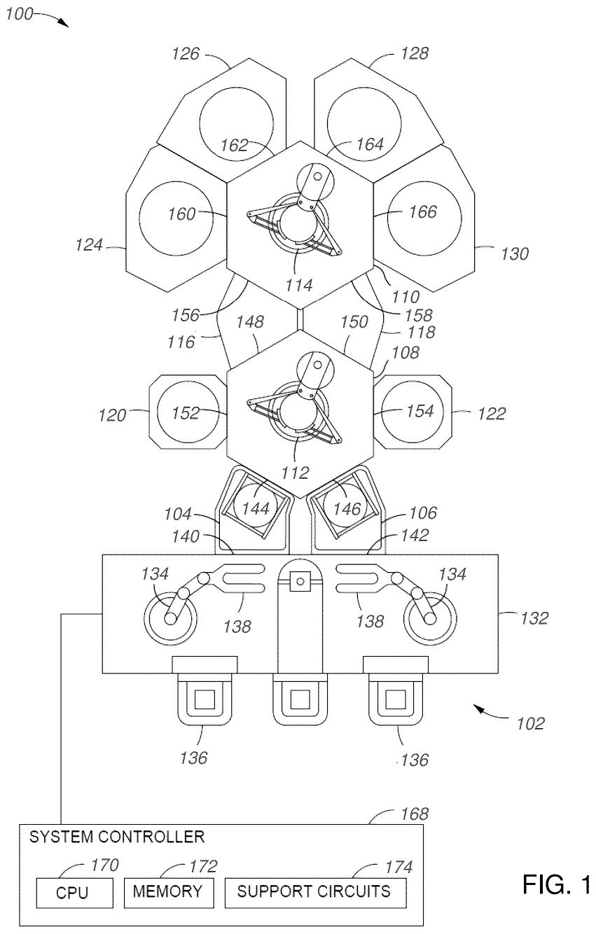

FIG. 1 is a schematic top view of a multi-chamber processing system 100, according to one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the processing system 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough.

Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing an etch process, the processing chamber 122 can be capable of performing a cleaning process, and the processing chambers 126, 128, 130 can be capable of performing respective epitaxial growth processes. The processing chamber 120 may be a Selectra™ Etch chamber available from Applied Materials of Santa Clara, Calif. The processing chamber 122 may be an Aktiv™ Pre-clean (APC) chamber available from Applied Materials of Santa Clara, Calif., a Pre-clean XT (MCxT-2) chamber, available from Applied Materials of Santa Clara, Calif., or a SiCoNi™ Pre-clean chamber available from Applied Materials of Santa Clara, Calif. The processing chamber 126, 128, or 130 may be a Centura™ Epi chamber, a Volta™ CVD/ALD chamber, an Encore™ PVD chamber, a selective tungsten deposition chamber, an ionized metal plasma physical vapor deposition (IMP PVD) chamber, a rapid thermal process (RTP) chamber, or a plasma etch (PE) chamber, available from Applied Materials of Santa Clara, Calif.

A system controller 168 is coupled to the processing system 100 for controlling the processing system 100 or components thereof. For example, the system controller 168 may control the operation of the processing system 100 using a direct control of the chambers 104, 106, 108, 110, 116, 118, 120, 122, 124, 126, 128, 130 of the processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general-purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

### Example Semiconductor Structure

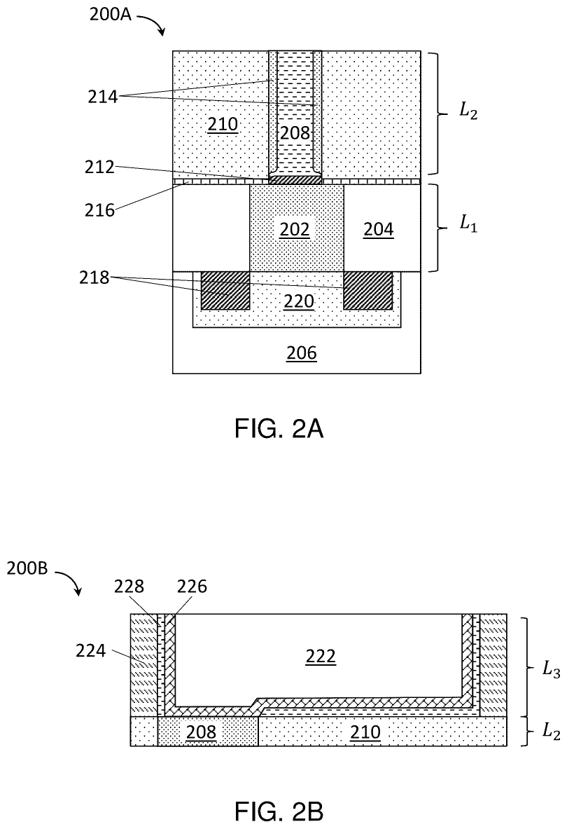

FIGS. 2A and 2B are schematic views of an exemplary semiconductor structure 200. FIG. 2A illustrates a middle-end-of-line (MEOL) portion 200A of the semiconductor structure 200. FIG. 2B illustrates a back-end-of-the-line (BEOL) portion 200B of the semiconductor structure 200.

The MEOL portion 200A may include a first level L₁ that includes a metal layer 202 (also referred to as “VD”) within a first dielectric layer 204 formed on a substrate 206, and a second level L₂ (also referred to as “M0 level”) that includes an interconnect 208 within a second dielectric layer 210 formed on the first level L₁. At an interface between the metal layer 202 and the interconnect 208, a metal capping layer 212 is disposed to improve the contact resistance of the interconnect 208. In the second level L₂, a barrier layer 214 may be formed around the interconnect 208. Between the first level L₁ and the second level L₂, an etch stop layer (ESL) 216 is disposed.

The substrate 206 may include heavily doped regions 218 and a lightly doped region 220 (also referred to as “MD”).

The term “substrate” as used herein refers to a layer of material that serves as a basis for subsequent processing operations and includes a surface to be cleaned. The substrate 206 may be a silicon based material or any suitable insulating materials or conductive materials as needed. The substrate 206 may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

The metal layer 202 and the interconnect 208 may be formed of tungsten (W), tungsten carbide (WC), tungsten nitride (WN), or molybdenum (Mo).

The first dielectric layer 204 may be formed of dielectric material such as silicon oxide (SiO₂), silicon nitride (Si₃N₄), silicon oxynitride (SiOₓN_{y}), hafnium containing material, such as hafnium oxides (HfOₓ including HfO₂), hafnium silicate (HfSiₓO_{y} including HfSiO₄), hafnium, silicon oxynitride (HfSiₓO_{y}N_{z}), hafnium oxynitride (HfOₓN_{y}), hafnium aluminates (HfAlₓO_{y}), hafnium aluminum silicate (HfAlₓSi_{y}O_{z}), hafnium aluminum silicon oxynitride (HfAl_{w}SiₓO_{y}N_{z}), hafnium lanthanum oxide (HfLaₓO_{y}), zirconium containing material, such as zirconium oxide (ZrOₓ including ZrO₂), zirconium silicate (ZrSiₓO_{y} including ZrSiO₄), zirconium silicon oxynitride (ZrSiₓO_{y}N_{z}), zirconium oxynitride (ZrOₓN_{y}), zirconium aluminates (ZrAlₓO_{y}), zirconium aluminum silicate (ZrAlₓSi_{y}O_{z}), zirconium aluminum silicon oxynitride (ZrAl_{w}SiₓO_{y}N_{z}), zirconium lanthanum oxide (ZrLaₓO_{y}), other aluminum-containing material or lanthanum-containing material, such as aluminum oxide (Al₂O₃ or AlOₓ), aluminum oxynitride (AlOₓN_{y}), aluminum silicate (AlSiₓO_{y}), aluminum silicon oxynitride (AlSiₓO_{y}N_{z}), lanthanum aluminum oxide (LaAlₓO_{y}), lanthanum oxide (LaOₓ or La₂O₃), other suitable material, a composite thereof, or combinations thereof. Other dielectric materials that may be used for the first dielectric layer 204 include titanium oxide (TiOₓ or TiO₂), titanium oxynitride (TiOₓN_{y}), tantalum oxide (TaOₓ or Ta₂O₅) and tantalum oxynitride (TaOₓN_{y}). The second dielectric layer 210 may be formed of low-k dielectric material such as silicon oxycarbide (SiOC).

The barrier layer 214 may be formed of titanium nitride (TiN), or tungsten (W).

The metal capping layer 212 may be formed of tungsten (W) having a thickness of between about 20 Å and about 40 Å, for example, about 20 Å. The ESL 216 may be formed of aluminum oxide (Al₂O₃).

The BEOL portion 200B may include the second level L₂ that includes the interconnect 208 formed within the second dielectric layer 210 and a third level L₃ (also referred to as “M1 level”) that includes a metal layer 222 formed within a third dielectric layer 224. In the third level L₃, barrier layers 226 may be formed around the metal layer 222, and liners 228 may be formed around the barrier layers 226. The metal layer 222 may be formed of copper (Cu). The third dielectric layer 224 may be formed dielectric material such as silicon oxide (SiO₂), silicon nitride (Si₃N₄), or silicon oxynitride (SiON). The barrier layers 226 may be formed of titanium (Ti) or tantalum (Ta). The liners 228 may be formed of titanium nitride (TiN), tantalum nitride (TaN), or tungsten (W).

### Post-Treatment of Dielectric Surface

During the fabrication of a MEOL portion of a semiconductor structure, exposed surfaces of a dielectric layer (e.g., inner sidewalls of a via formed in the dielectric layer) are pre-cleaned to remove residues (e.g., tungsten (W) or chlorine (Cl₂)) before depositing a barrier layer on the exposed surfaces of the dielectric layer. Conventionally, pre-cleaning is performed by a plasma treatment, such as a remote plasma assisted process or a capacitively coupled plasma (CCP) process, in which dielectric surfaces are damaged. The method described herein includes a water (H₂O) soak process that effectively removes tungsten residues or chlorine residues from exposed surfaces of a dielectric layer. The water (H₂O) soak can be done in the same processing chamber as a pre-clean process to pre-clean a surface of a metal layer, without vacuum break.

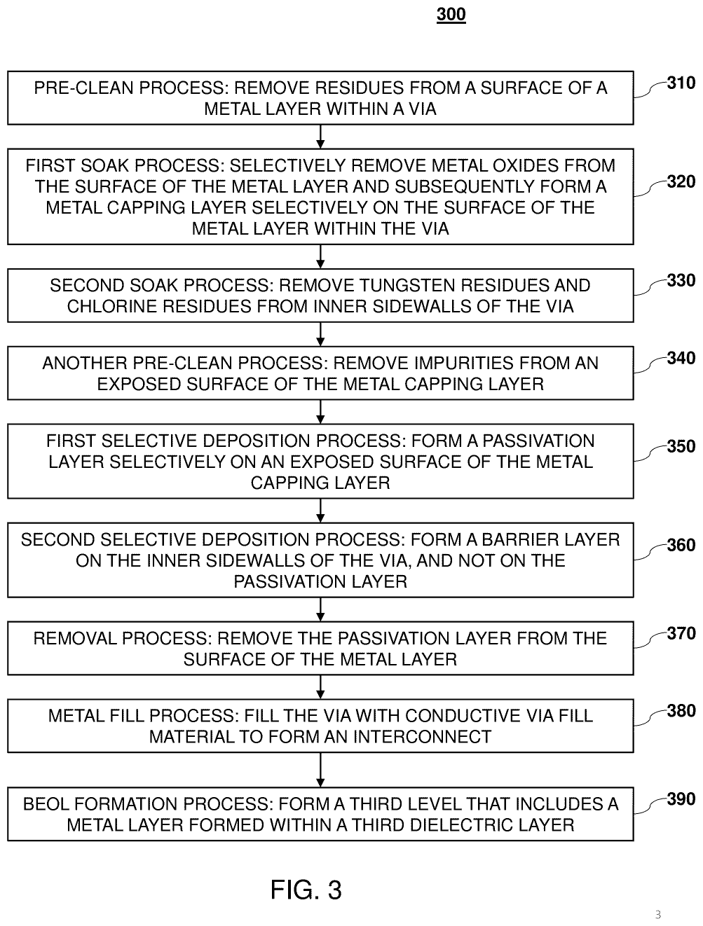

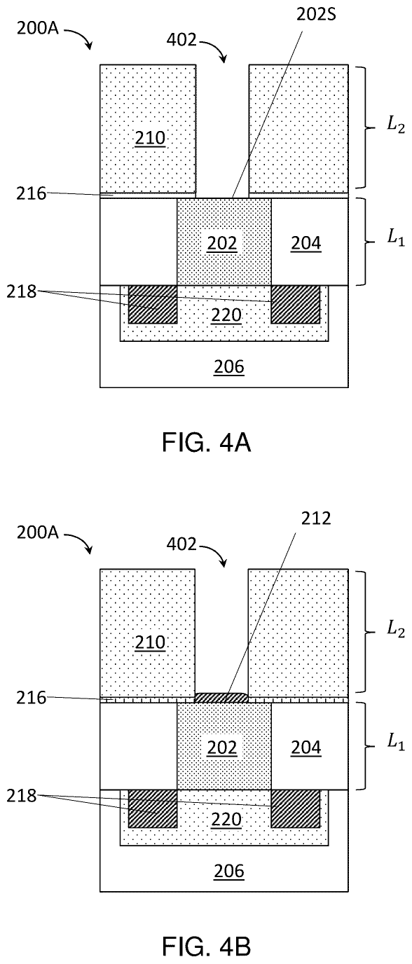

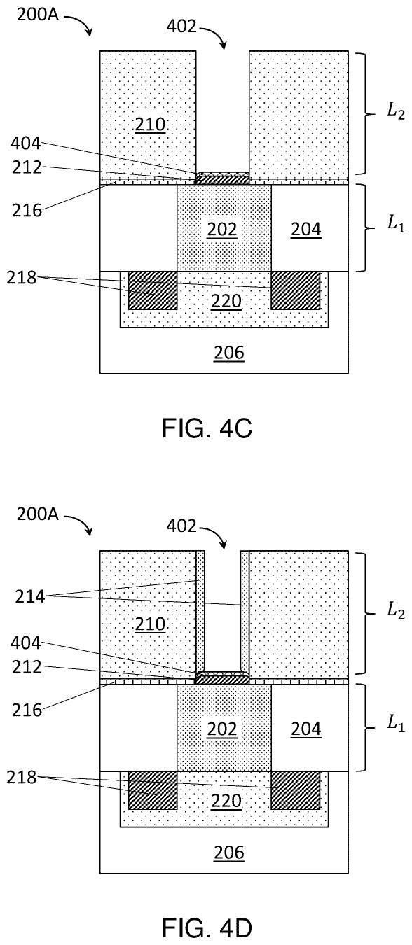

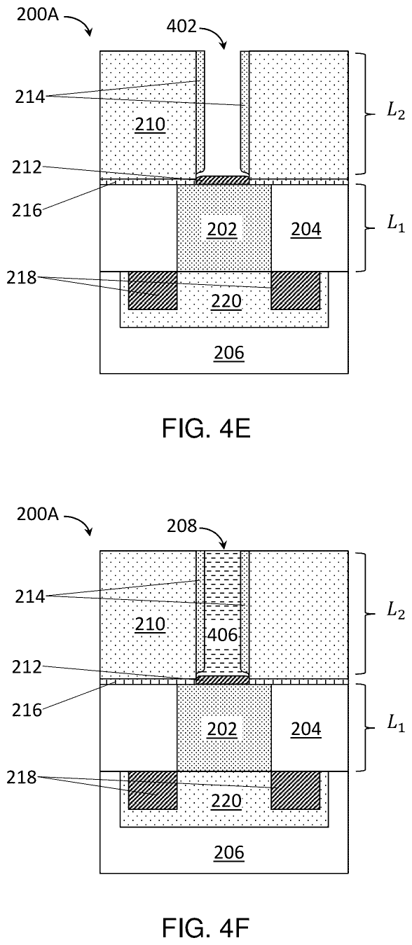

FIG. 3 depicts a process flow diagram of a method 300 of forming a semiconductor structure 200 having the MEOL portion 200A and a BEOL portion 200B, shown in FIGS. 2A and 2B, according to one or more embodiments of the present disclosure. FIGS. 4A, 4B, 4C, 4D, 4E, and 4F are cross-sectional views of a portion of the semiconductor structure 200 corresponding to various states of the method 300. It should be understood that FIGS. 4A, 4B, 4C, 4D, 4E, and 4F illustrate only partial schematic views of the semiconductor structure 200, and the semiconductor structure 200 may contain any number of transistor sections and additional materials having aspects as illustrated in the figures. It should also be noted that although the method illustrated in FIG. 3 is described sequentially, other process sequences that include one or more operations that have been omitted and/or added, and/or has been rearranged in another desirable order, fall within the scope of the embodiments of the disclosure provided herein.

As shown in FIG. 4A, the MEOL portion 200A of the semiconductor structure 200 includes a first level L₁ that includes a metal layer 202 (also referred to as “VD”) within a first dielectric layer 204 formed on a substrate 206, and a second level L₂ that includes a second dielectric layer 210 having a via 402 formed therein on the first level L₁. An interconnect 208 (not shown in FIG. 4A) will be formed within the via 402.

The metal layer 202 and the interconnect 208 may be formed of tungsten (W), tungsten carbide (WC), tungsten nitride (WN), or molybdenum (Mo). The first dielectric layer 204 and the second dielectric layer 210 may be each formed of dielectric material such as silicon oxide (SiO₂), silicon nitride (Si₃N₄), silicon oxynitride (SiOₓN_{y}), hafnium containing material, such as hafnium oxide (HfOₓ including HfO₂), hafnium silicate (HfSiₓO_{y} including HfSiO₄), hafnium, silicon oxynitride (HfSiₓO_{y}N_{z}), hafnium oxynitride (HfOₓN_{y}), hafnium aluminates (HfAlₓO_{y}), hafnium aluminum silicate (HfAlₓSi_{y}O_{z}), hafnium aluminum silicon oxynitride (HfAl_{w}SiₓO_{y}N_{z}), hafnium lanthanum oxide (HfLaₓO_{y}), zirconium containing material, such as zirconium oxide (ZrOₓ including ZrO₂), zirconium silicate (ZrSiₓO_{y} including ZrSiO₄), zirconium silicon oxynitride (ZrSiₓO_{y}N_{z}), zirconium oxynitride (ZrOₓN_{y}), zirconium aluminates (ZrAlₓO_{y}), zirconium aluminum silicate (ZrAlₓSi_{y}O_{z}), zirconium aluminum silicon oxynitride (ZrAl_{w}SiₓO_{y}N_{z}), zirconium lanthanum oxide (ZrLaₓO_{y}), other aluminum-containing material or lanthanum-containing material, such as aluminum oxide (Al₂O₃ or AlOₓ), aluminum oxynitride (AlOₓN_{y}), aluminum silicate (AlSiₓO_{y}), aluminum silicon oxynitride (AlSiₓO_{y}N_{z}), lanthanum aluminum oxide (LaAlₓO_{y}), lanthanum oxide (LaOₓ or La₂O₃), other suitable material, a composite thereof, or a combination. Other dielectric materials that may be used for the first dielectric layer 204 and the second dielectric layer 210 include titanium oxide (TiOₓ or TiO₂), titanium oxynitride (TiOₓN_{y}), tantalum oxide (TaOₓ or Ta₂O₅) and tantalum oxynitride (TaOₓN_{y}).

The substrate 206 may include heavily doped regions 218 and a lightly doped region 220 (also referred to as “MD”). Between the first level L₁ and the second level L₂, an etch stop layer (ESL) 216 is disposed. The ESL 216 may be formed of aluminum oxide (Al₂O₃).

The method 300 begins with block 310, in which a pre-clean process is performed to remove residues from a surface 202S of the metal layer 202 within the via 402. The pre-clean process may be performed in a pre-clean chamber, such as the processing chamber 122 shown in FIG. 1.

During the fabrication of the second level L₂, the semiconductor structure 200 may be exposed to air or other oxidizing environment, and thus the surface 202S of the metal layer 202 may be oxidized. Further, an etching process to form the via 402 within the second dielectric layer 210 may also leave residues, such as chlorine residues or fluorine residues, on the surface 202S of the metal layer 202. The surface 202S of the metal layer 202 within the via 402 is therefore pre-cleaned prior to filling the via 402 from a bottom surface of the via 402 (the surface 202S of the metal layer 202) to form the interconnect 208.

The pre-clean process may include a plasma treatment process to remove chlorine or fluorine residues from the surface 202S of the metal layer 202. The plasma treatment process includes exposing the surface 202S of the metal layer 202 to a plasma formed from a process gas including hydrogen (H₂)-containing gas and helium (He)-containing gas. The plasma treatment process may be a radical-based pre-cleaning technique using a remote plasma assisted process in a processing chamber, such as Aktiv™ Pre-clean (APC) chamber available from Applied Materials of Santa Clara, Calif. The plasma treatment process may be a capacitively coupled plasma (CCP) process performed in a processing chamber, such as Pre-clean XT (MCxT-2) chamber available from Applied Materials of Santa Clara, Calif. The plasma treatment process may be performed at a temperature of between about 300° C. and about 400° C., for example, about 345° C. and at a pressure of between about 100 mTorr and about 500 mTorr, for example, about 300 mTorr, for a duration of between about 10 seconds and about 120 seconds, for example, about 25 seconds. During the plasma treatment process, helium (He) gas may be supplied at a flow rate of between about 300 sccm and about 500 sccm, for example, about 380 sccm, and hydrogen (H₂) gas may be supplied at a flow rate of between about 10 sccm and 50 sccm, for example about 20 sccm.

In block 320, a first soak process is performed to selectively remove metal oxides (e.g., selectively removing metal oxides, such as tungsten oxide (WOₓ) or molybdenum oxide (MoOₓ) (x=2 or 3) from the surface 202S of the metal layer 202 and subsequently form a metal capping layer 212 selectively on the surface 202S of the metal layer 202 within the via 402, as shown in FIG. 4B. The metal capping layer 212 may be formed of tungsten (W) having a thickness of between about 20 Å and about 40 Å, for example, about 20 Å. The first soak process is performed in a processing chamber, such as the processing chamber 122 shown in FIG. 1.

The first soak process may include a pre-clean process and a fluorine-free tungsten (FFW) growth process using a chemical vapor deposition (CVD) technique, in which the surface 202S of the metal layer 202 is soaked in a precursor including tungsten chloride (WCl₅) gas that is provided in a pulsing flow in the processing chamber. The surface 202S of the metal layer 202 is pre-cleaned in the pre-clean process. Subsequently, in the FFW growth process, a metal capping layer 212 is formed selectively on the surface 202S of the metal layer 202 within the via 402 of tungsten (W) is formed by reaction of the precursor gas (e.g., WCl₅) with hydrogen (H₂). The first soak process is performed at a temperature of between about 400° C. and about 450° C., for example, about 420° C. at a pressure of between about 10 Torr and about 50 Torr, for example, about 15 Torr, for a duration of between about 30 seconds and about 5 minutes, for example, about 4 minutes.

In block 330, a second soak process is performed to remove tungsten residues and chlorine residues from inner sidewalls of the via 402 (e.g., exposed surfaces of the second dielectric layer 210). The second soak process is performed in the same processing chamber as the pre-clean process in block 310, such as the processing chamber 122 shown in FIG. 1.

In the second soak process, the surface 202S of the metal layer 202 is soaked in a precursor including water (H₂O) that is provided in a pulsing flow or a continuous flow in the processing chamber. The second soak process is performed at a temperature of between about 300° C. and about 450° C., for example, about 350° C. and at a pressure of between about 5 Torr and about 300 Torr, for example, about 7.5 Torr, for a duration of between about 30 seconds and about 300 seconds, for example, about 120 seconds. During the second soak process, water (H₂O) may be supplied at a flow rate of between about 10 sccm and about 200 sccm, for example, about 30 sccm, hydrogen (H₂) gas may be supplied at a flow rate of between about 500 sccm and 1500 sccm, for example about 1000 sccm, and argon (Ar) gas may be supplied at a flow rate of between about 500 sccm and 1500 sccm, for example about 1000 sccm.

The inventors have discovered that a water (H₂O) soak process can effectively remove tungsten (W) residues and chlorine residues from a dielectric surface, about 87% of chlorine residues and about 32.5% of tungsten residues.

The pre-clean process in block 310, the first soak process in block 320, and the second soak process in block 330 may be performed in the same chamber, such as the processing chamber 122 shown in FIG. 1, without vacuum break. Subsequent to the second soak process in block 330, the semiconductor structure 200 undergoes vacuum break for further fabrication.

In block 340, another pre-clean process is performed to remove impurities from an exposed surface of the metal capping layer 212. The pre-clean process in block 340 is the same as or similar to the pre-clean process in block 310.

In block 350, a first selective deposition process is performed to form a passivation layer 404 selectively on an exposed surface of the metal capping layer 212 (e.g, tungsten (W)), as shown in FIG. 4C. The first selective deposition process may be a soaking process performed in a processing chamber, such as the processing chamber 124, 126, 128, or 130 shown in FIG. 1.

The passivation layer 404 may be formed of a self-assembled monolayer (SAM) of organic molecules. In the soaking process, the semiconductor structure 200 is soaked in a gas precursor including an unsaturated hydrocarbon, at a temperature of about between 350° C. and about 400° C. and a pressure of between 10 Torr and 60 Torr for a duration of between about 30 seconds and about 200 seconds, with a flow rate of the precursor of between about 300 sccm and about 600 sccm. In some embodiments, a liquid precursor is used in the soaking process. In the soaking process, organic molecules in the precursor are absorbed only on a metal surface, such as the exposed surface of the metal capping layer 212. The passivation layer 404 may act as a block layer that suppresses nucleation or growth of a subsequent material deposition thereon.

In block 360, a second selective deposition process is performed to form a barrier layer 214 on the inner sidewalls of the via 402, and not on the passivation layer 404, as shown in FIG. 4D. The second selective deposition process may include an atomic layer deposition (ALD) process in a processing chamber, such as the processing chamber 124, 126, 128, or 130 shown in FIG. 1.

The barrier layer 214 may be formed of tantalum nitride (TaN) or doped tantalum nitride (TaN), metal doped TaN, titanium nitride (TiN), tungsten nitride (WN), or tungsten nitride carbide (WCN).

In block 370, subsequent to the second selective deposition process in block 260, a removal process is performed to remove the passivation layer 404 from the surface 202S of the metal layer 202, as shown in FIG. 4E. The removal process may include a dry etch process in an etch chamber, such as the processing chamber 122 shown in FIG. 1.

The removal process may include an anisotropic remote plasma assisted dry etch process, such as a reactive ion etching (RIE) process, using a plasma formed from a gas including argon (Ar), helium (He), nitrogen (N₂), hydrogen (H₂), ammonia (NH₃), or a combination thereof. The plasma effluents directionally bombard and remove the passivation layer 404.

In block 380, a metal fill process is performed to fill the via 402 with conductive via fill material 406 to form an interconnect 208, as shown in FIG. 2A. The metal fill process may include any appropriate deposition process, such as atomic layer deposition (ALD), chemical vapor deposition (CVD), or a wet process including electrical plating, in a processing chamber, such as the processing chamber 124, 126, 128, or 130 shown in FIG. 1.

In the metal fill process, the semiconductor structure 200 is exposed to a precursor including the conductive via fill material 406, which grows from the exposed surface of the metal capping layer 212 (e.g., tungsten (W)) at a faster rate, for example, about ten times faster, than that from the exposed surface of the barrier layer 214 (e.g., tantalum nitride (TaN)). The conductive via fill material 406 may be tungsten (W), tungsten carbide (WC), tungsten nitride (WN), or molybdenum (Mo).

In block 390, a BEOL formation process is performed to form a third level L₃ that includes a metal layer 222 formed within a third dielectric layer 224, as shown in FIG. 2B.

The embodiments described herein provide a system and a method used to prepare and grow a selective capping layer on a metal layer within a via during a back-end-of-the-line (BEOL) process. The methods disclosed herein include a post-treatment (H₂O soak) that significantly reduces the level of tungsten/chloride residues on dielectric surfaces and recover a tantalum nitride (TaN) barrier better than the other conventional processes, such as a remote plasma assisted process or a capacitively coupled plasma (CCP) process, without damaging dielectric surfaces.

While the foregoing is directed to embodiments of the present disclosure, other and further embodiments of the disclosure may be devised without departing from the basic scope thereof, and the scope thereof is determined by the claims that follow.

We claim:

1. A semiconductor structure comprising:
a first level comprising a metal layer within a first dielectric layer formed on a substrate;
a second level formed on the first level, the second level comprising an interconnect within a second dielectric layer and a barrier layer formed around the interconnect; and
a metal capping layer disposed at an interface between the metal layer and the interconnect, wherein
the metal capping layer comprises tungsten (W) and has a thickness of between 20 Å and 40 Å.

2. The semiconductor structure of claim 1, wherein:
the metal layer and the interconnect each comprise tungsten (W), tungsten carbide (WC), tungsten nitride (WN), or molybdenum (Mo); and
the first dielectric layer and the second dielectric layer each comprise silicon oxide (SiO₂), silicon nitride (Si₃N₄), silicon oxynitride (SiOₓN_{y}), hafnium containing material, zirconium containing material, aluminum-containing material, lanthanum-containing material, or a combination thereof.

3. The semiconductor structure of claim 1, wherein the barrier layer comprises tantalum nitride (TaN).

4. A method of post-treatment in a middle-end-of-line (MEOL) portion of a semiconductor structure, comprising:
performing a first pre-clean process to remove residues from a surface of a metal layer within a via formed in a dielectric layer;
performing a first soak process, comprising:
a second pre-clean process to remove metal oxides from the surface of the metal layer within the via; and
a fluorine-free tungsten (FFW) growth process to form a metal capping layer on the surface of the metal layer; and
performing a second soak process to remove residues from exposed surfaces of the dielectric layer on inner sidewalls of the via.

5. The method of claim 4, wherein:
the metal layer comprises tungsten (W), tungsten carbide (WC), tungsten nitride (WN), or molybdenum (Mo), and
the dielectric layer comprises silicon oxide (SiO₂), silicon nitride (Si₃N₄), silicon oxynitride (SiOₓN_{y}), hafnium containing material, zirconium containing material, aluminum-containing material, lanthanum-containing material, or a combination thereof.

6. The method of claim 4, wherein the first pre-clean process, the first soak process, and the second soak process are performed in a same processing chamber without vacuum break.

7. The method of claim 4, wherein the first pre-clean process and the third pre-clean process each comprise a remote plasma assisted process using hydrogen (H₂)-containing gas and helium (He)-containing gas.

8. The method of claim 4, where the first soak process comprises soaking the surface of the metal layer in a precursor including tungsten chloride (WCl₅) gas that is provided in a pulsing flow in a processing chamber.

9. The method of claim 8, wherein the metal capping layer comprises tungsten (W) having of between 20 Å and 40 Å.

10. The method of claim 4, wherein the second soak process comprises soaking the surface of the metal layer in a precursor including water (H₂O) that is provided in a pulsing flow or a continuous flow in a processing chamber.

11. A method of forming a middle-end-of-line (MEOL) portion of a semiconductor structure, comprising:
performing a first pre-clean process to remove residues from a surface of a metal layer within a via formed in a dielectric layer;
performing a first soak process, comprising:
a second pre-clean process to remove metal oxides from the surface of the metal layer within the via; and
a fluorine-free tungsten (FFW) growth process to form a metal capping layer on the surface of the metal layer;
performing a second soak process to remove residues from inner sidewalls of the via;
performing a third pre-clean process to remove residues from the surface of the metal layer within the via;
performing a first selective deposition process to form a passivation layer selectively on an exposed surface of the metal capping layer;
performing a second selective deposition process to form a barrier layer on inner sidewalls of the via;
performing a removal process to remove the passivation layer from the surface of the metal layer; and
performing a metal fill process to fill the via with conductive via fill material.

12. The method of claim 11, wherein:
the metal layer comprises tungsten (W), tungsten carbide (WC), tungsten nitride (WN), or molybdenum (Mo), and
the dielectric layer comprises silicon oxide (SiO₂), silicon nitride (Si₃N₄), silicon oxynitride (SiOₓN_{y}), hafnium containing material, zirconium containing material, aluminum-containing material, lanthanum-containing material, or a combination thereof.

13. The method of claim 11, wherein the first pre-clean process and the third pre-clean process each comprise a remote plasma assisted process using hydrogen (H₂)-containing gas and helium (He)-containing gas.

14. The method of claim 11, where the first soak process comprises soaking the surface of the metal layer in a precursor including tungsten chloride (WCl₅) gas that is provided in a pulsing flow in a processing chamber.

15. The method of claim 14, wherein the metal capping layer comprises tungsten (W) having of between 20 Å and 40 Å.

16. The method of claim 11, wherein the second soak process comprises soaking the surface of the metal layer in a precursor including water (H₂O) that is provided in a pulsing flow or a continuous flow in a processing chamber.

17. The method of claim 11, wherein the first selective deposition process comprises a soaking process, and the passivation layer comprises self-assembled monolayer (SAM) of organic molecules.

18. The method of claim 11, wherein the second selective deposition process comprises an atomic layer deposition (ALD) process, and the barrier layer comprises tantalum nitride (TaN).

19. The method of claim 11, wherein the removal process comprises a dry etch process.

20. The method of claim 11, wherein the conductive via fill material comprises tungsten (W), tungsten carbide (WC), tungsten nitride (WN), or molybdenum (Mo).
